(19) United States
(12) Patent Application Publication
(10) Pub. No.: US 2026/0068097 A1
(43) Pub. Date: Mar. 5, 2026

(54) HEAT SPREADER AND METHOD OF MAKING HEAT SPREADER

(71) Applicant: SHINKO ELECTRIC INDUSTRIES CO., LTD., Nagano (JP)

(72) Inventor: Takumi MATSUMOTO, Nagano (JP)

(21) Appl. No.: 19/308,705

(22) Filed: Aug. 25, 2025

(30) Foreign Application Priority Data
Aug. 28, 2024 (JP) 2024-146308

(51) Int. Cl. H05K 7/20

(52) U.S. Cl. CPC H05K 7/20436

(57) ABSTRACT

A heat spreader includes a flat portion having a first flat surface and a second flat surface opposite the first flat surface, a first convex portion surrounded by the first flat surface and projecting from the first flat surface to a side opposite the second flat surface, and a second convex portion surrounded by the second flat surface and projecting from the second flat surface to a side opposite the first flat surface.

### CROSS-REFERENCE TO RELATED APPLICATIONS

The present application is based on and claims priority to Japanese Patent Application No. 2024-146308 filed on Aug. 28, 2024, with the Japanese Patent Office, the entire contents of which are incorporated herein by reference.

### FIELD

The disclosures herein relate to heat spreaders and methods of making a heat spreader.

### BACKGROUND

Heat spreaders are used to transmit heat generated in semiconductor chips to heat sinks.

Recently, with the increase of heat generation in semiconductor chips, there has been a growing demand for improvement of efficiency of heat transfer to heat sinks.

There may be a need to provide a heat spreader effectively improving the heat transfer efficiency and a method of making such a heat spreader.

### RELATED-ART DOCUMENTS

[Patent Document 1] Japanese Laid-Open Patent Publication No. 2022-91491
[Patent Document 2] Japanese Laid-Open Patent Publication No. 2010-135459

### SUMMARY

According to an embodiment, a heat spreader includes a flat portion having a first flat surface and a second flat surface opposite the first flat surface, a first convex portion surrounded by the first flat surface and projecting from the first flat surface to a side opposite the second flat surface, and a second convex portion surrounded by the second flat surface and projecting from the second flat surface to a side opposite the first flat surface.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of a heat spreader according to a first embodiment;

FIGS. 2A through 2C are cross-sectional views illustrating an example of a method of making the heat spreader according to the first embodiment;

FIGS. 3A through 3C are cross-sectional views illustrating the example of the method of making the heat spreader according to the first embodiment;

FIGS. 4A and 4B are drawings illustrating an example of a set of molding parts used in the manufacturing process of the heat spreader according to the first embodiment;

FIGS. 5A and 5B are drawings illustrating an example of a set of molding parts used in the manufacturing process of the heat spreader according to the first embodiment;

FIGS. 6A and 6B are drawings illustrating an example of a set of molding parts used in the manufacturing process of the heat spreader according to the first embodiment;

FIGS. 7A and 7B are drawings illustrating an example of a set of molding parts used in the manufacturing process of the heat spreader according to the first embodiment;

FIGS. 8A and 8B are cross-sectional views illustrating an example of a method of making a semiconductor device using the heat spreader according to the first embodiment;

FIGS. 9A and 9B are drawings illustrating an example of a heat spreader according to a second embodiment; and

FIGS. 10A and 10B are drawings illustrating an example of a heat spreader according to a third embodiment.

### DESCRIPTION OF EMBODIMENTS

Embodiments will be specifically described below with reference to the attached drawings. In this specification and the drawings, components having substantially the same functional structure may be denoted by the same reference numerals, and duplicate descriptions thereof are omitted. In the following description, the XYZ Cartesian coordinate system will be used. With respect to any given reference point, the positive Z direction may be referred to by using terms such as above, up, upper, and top, and the negative Z direction may be referred to by using terms such as below, down, lower, and bottom. In addition, the surface facing down may be referred to as an A-side surface or a lower surface, and the surface facing up may be referred to as a B-side surface or an upper surface. However, the coordinate system is specified for the purpose of explanation and does not limit the orientation of the heat spreader. The heat spreader may be used upside down or may be arranged at any angle. Further, the plan view of an object refers to the view of the object as seen from the direction normal to the upper surface of the heat spreader, and the plane shape of an object refers to the shape of the object as seen from the direction normal to the upper surface of the heat spreader. In this disclosure, a flat surface refers to a surface that is not intentionally curved or made uneven. The flat surface is such that its arithmetic average roughness Ra is 0.125 μm or less.

### First Embodiment

A first embodiment is described below. The first embodiment is directed to a heat spreader.

### [Structure of Heat Spreader]

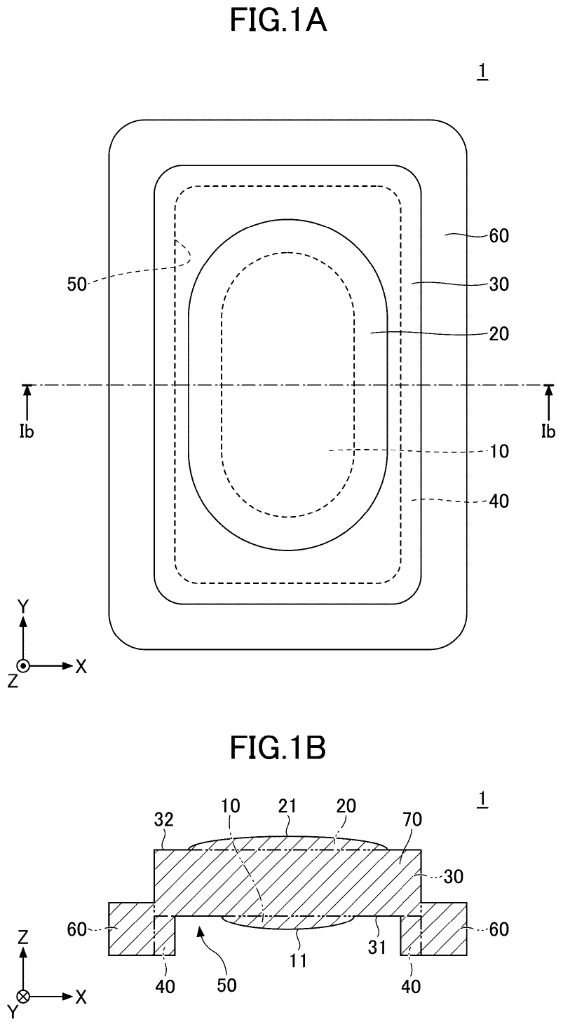

This section will describe the structure of a heat spreader according to the first embodiment. FIGS. 1A and 1B are views illustrating an example of a heat spreader according to the first embodiment. FIG. 1A is a plan view and FIG. 1B is a cross-sectional view. FIG. 1B corresponds to a cross-section taken along the line Ib-Ib in FIG. 1A.

As illustrated in FIGS. 1A and 1B, a heat spreader 1 according to the first embodiment includes a flat portion 30, a first convex portion 10, a second convex portion 20, an extended portion 40, and a flange portion 60. The heat spreader 1 is formed of, for example, one metal plate 70. The metal plate 70 contains, for example, copper (Cu). The metal plate 70 may be a copper plate.

The flat portion 30 has a first flat surface 31 and a second flat surface 32 opposite to the first flat surface 31. The first flat surface 31 is located in the negative Z direction relative to the second flat surface 32.

The first convex portion 10 is surrounded by the first flat surface 31 and projects from the first flat surface 31 to the side (i.e., negative Z side) opposite to the second flat surface 32 side (i.e., positive Z side). The first convex portion 10 has a first curved surface 11. The first curved surface 11 connects to the first flat surface 31 and bulges toward the negative Z side from the first flat surface 31. In this embodiment, the entire surface of the first convex portion 10 on the negative Z side is the first curved surface 11. The height of the first convex portion 10 from the first flat surface 31 is, for example, from 0.005 mm to 0.5 mm. In plan view, for example, the outer shape of the first convex portion 10 has two straight sections extending along the Y axis and two circular arcs connected to both ends of the straight sections, with its dimension in the Y-axis direction being greater than the dimension in the X-axis direction. The outer shape of the first convex portion 10 may alternatively be elliptical, rectangular, or circular.

The second convex portion 20 is surrounded by the second flat surface 32 and projects from the second flat surface 32 to the side (positive Z side) opposite to the first flat surface 31 side (negative Z side). The second convex portion 20 has a second curved surface 21. The second curved surface 21 connects to the second flat surface 32 and bulges to the positive Z side from the second flat surface 32. In this embodiment, the entire surface of the second convex portion 20 on the positive Z side is the second curved surface 21. The height of the second convex portion 20 from the second flat surface 32 is, for example, from 0.005 mm to 0.5 mm. In plan view, for example, the outer shape of the second convex portion 20 has two straight sections extending along the Y-axis and two circular arcs connected to both ends of the straight sections, with its dimension in the Y-axis direction being greater than the dimension in the X-axis direction. The outer shape of the second convex portion 20 may alternatively be elliptical, rectangular, or circular.

The extended portion 40 is connected to the flat portion 30 and extends from the first flat surface 31 to the side (negative Z side) opposite to the second flat surface 32 side (positive Z side). In plan view, for example, the extended portion 40 surrounds the first convex portion 10. The extended portion 40 is spaced apart from the first convex portion 10. The height of the extended portion 40 from the first flat surface 31 is greater than the height of the first convex portion 10, and may be, for example, from 0.1 mm to 1 mm.

The flange portion 60 extends from the extended portion 40 and a part of the flat portion 30 in directions away from the first convex portion 10. The extended portion 40 and the flange portion 60 have, for example, faces that are flush with each other on the negative Z side.

The heat spreader 1 has a cavity 50 that is defined by the first flat surface 31, the first curved surface 11, and the side surface of the extended portion 40 facing toward the first convex portion 10. The depth of the cavity 50 is, for example, from 0.1 mm to 1 mm.

### [Method of Making Heat Spreader]

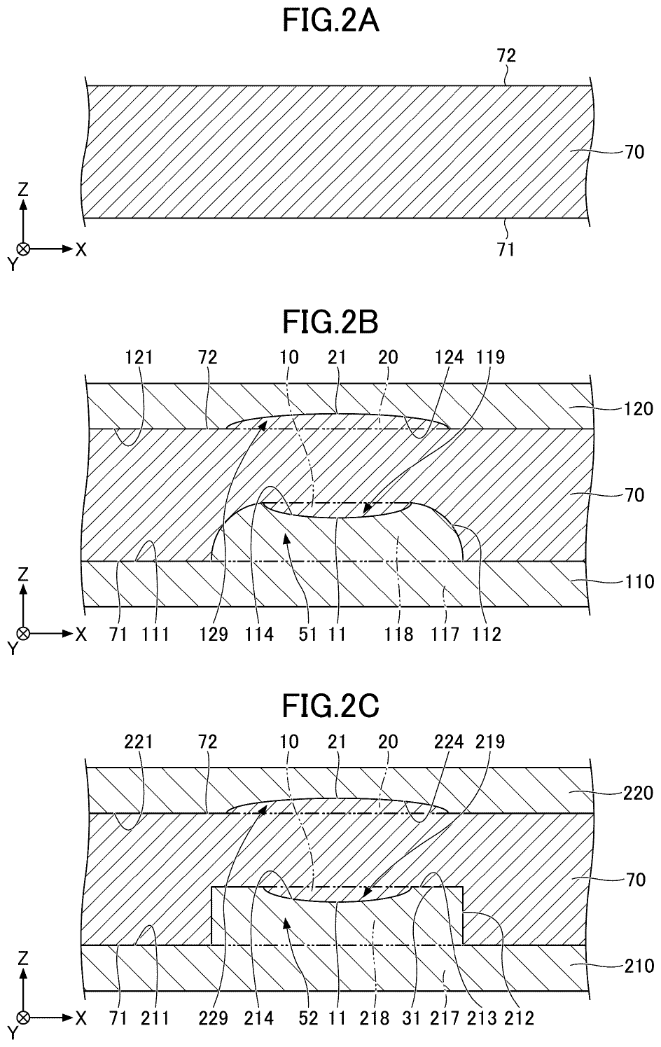

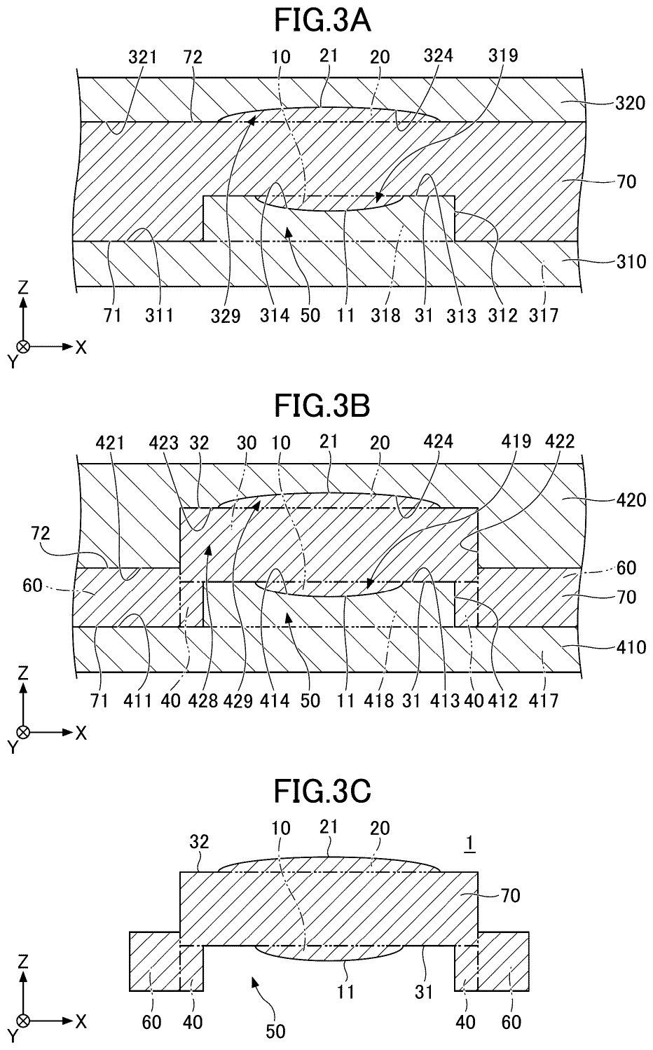

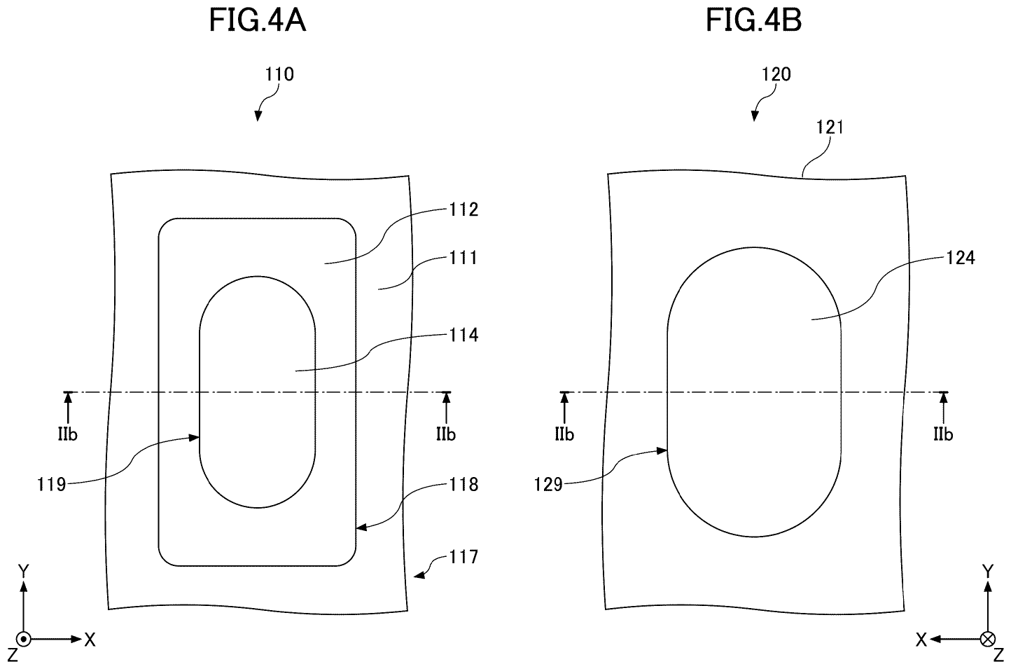

The method of making the heat spreader 1 according to the first embodiment is described below. FIGS. 2A through 2C and FIGS. 3A through 3C are cross-sectional views illustrating an example of a method of making the heat spreader 1 according to the first embodiment. FIGS. 4A and 4B to FIGS. 7A and 7B are views illustrating examples of sets of molding parts used in the method of making the heat spreader 1 according to the first embodiment. FIGS. 4A, 5A, 6A, and 7A are top views illustrating examples of lower molding parts, and FIGS. 4B, 5B, 6B, and 7B are bottom views illustrating examples of upper molding parts.

First, as illustrated in FIG. 2A, a metal plate 70 is prepared. The metal plate 70 has a first surface 71 and a second surface 72 opposite to the first surface 71. The first surface 71 is located in the negative Z direction relative to the second surface 72. The first surface 71 and the second surface 72 are, for example, flat surfaces.

Next, as illustrated in FIG. 2B, the metal plate 70 is pressed using molding parts 110 and 120. The material of the molding parts 110 and 120 includes cemented carbide such as tungsten carbide (WC). FIG. 2B corresponds to a cross-section taken along the line IIb-IIb in FIGS. 4A and 4B.

As illustrated in FIGS. 2B and 4A, the molding part 110 has a base portion 117 and a convex portion 118. A concave portion 119 is formed at the top of the convex portion 118. The base portion 117 has a flat surface 111 pressed against the first surface 71. The convex portion 118 is for forming a concave portion 51 in the metal plate 70 which serves as a basis for the cavity 50, and the outer shape of the convex portion 118 coincides with the outer shape of the cavity 50 in plan view. The convex portion 118 is surrounded by the flat surface 111 and projects from the flat surface 111 to the positive Z direction. The convex portion 118 has a convex surface 112. The convex surface 112 is connected to the flat surface 111 and extends from the flat surface 111 to the positive Z side. The concave portion 119 is for forming the first convex portion 10. The concave portion 119 has a concave surface 114. The concave surface 114 is connected to the top of the convex surface 112 and is recessed relative to the top of the convex surface 112 toward the negative Z side. The shape of the concave surface 114 coincides with the shape of the first curved surface 11.

As illustrated in FIGS. 2B and 4B, the molding part 120 has a flat surface 121 pressed against the second surface 72. A concave portion 129 is formed in the molding part 120. The concave portion 129 is for forming the second convex portion 20. The concave portion 129 has a concave surface 124. The concave surface 124 is connected to the flat surface 121 and is recessed toward the positive Z side relative to the flat surface 121. The shape of the concave surface 124 coincides with the shape of the second curved surface 21.

By pressing the metal plate 70 using the molding parts 110 and 120, the concave portion 51 and the first convex portion 10 are formed in the first surface 71 of the metal plate 70, and the second convex portion 20 is formed in the second surface 72. In this manner, pressing the metal plate 70 using the molding parts 110 and 120 shapes the first surface 71 and the second surface 72 simultaneously.

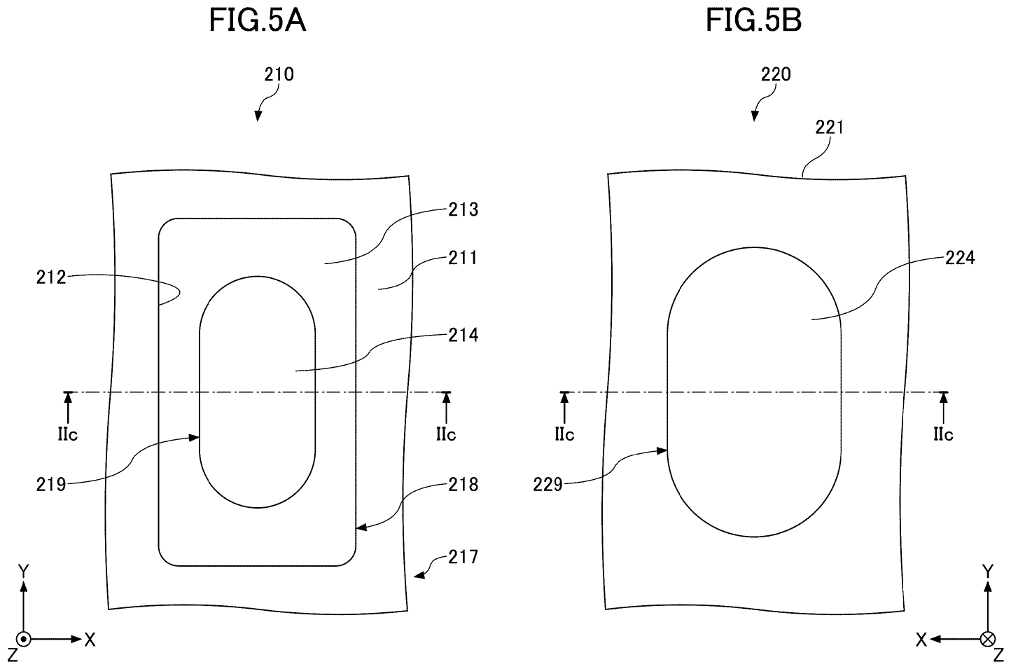

After pressing the metal plate 70 using the molding parts 110 and 120, the metal plate 70 is pressed using molding parts 210 and 220, as illustrated in FIG. 2C. The material of the molding parts 210 and 220 includes cemented carbide such as tungsten carbide (WC). FIG. 2C corresponds to a cross-section taken along the line IIc-IIc in FIGS. 5A and 5B.

As illustrated in FIGS. 2C and 5A, the molding part 210 includes a base 217 and a projection 218. A concave portion 219 is formed at the top of the projection 218. The base 217 has a flat surface 211 pressed against the first surface 71. The projection 218 is for enlarging the concave portion 51 to form a recess 52 in the metal plate 70, and the outer shape of the projection 218 coincides with the outer shape of the cavity 50 in plan view. The height of the projection 218 is larger than the depth of the cavity 50. The projection 218 is surrounded by the flat surface 211 and projects from the flat surface 211 to the positive Z side. The projection 218 has sidewall surfaces 212 and a flat surface 213. The sidewall surfaces 212 are connected to the flat surface 211 and are parallel to the Z axis. In plan view, the shape of the sidewall surfaces 212 coincides with the shape of the sidewall surfaces of the cavity 50. The flat surface 213 connects to the sidewall surfaces 212 and is perpendicular to the Z axis. The shape of the flat surface 213 coincides with the shape of the first flat surface 31, which is the end surface of the cavity 50. The concave portion 219 has a concave surface 214. The concave surface 214 is connected to the flat surface 213 and is recessed toward the negative Z side relative to the flat surface 213. The shape of the concave surface 214 coincides with the shape of the first curved surface 11.

As illustrated in FIGS. 2C and 5B, the molding part 220 has a flat surface 221 pressed against the second surface 72. A concave portion 229 is formed in the molding part 220. The concave portion 229 has a concave surface 224. The concave surface 224 is connected to the flat surface 221 and is recessed toward the positive Z side relative to the flat surface 221. The shape of the concave surface 224 coincides with the shape of the second curved surface 21.

By pressing the metal plate 70 with the molding parts 210 and 220, the recess 52 enlarged from the concave portion 51 is formed in the first surface 71 of the metal plate 70.

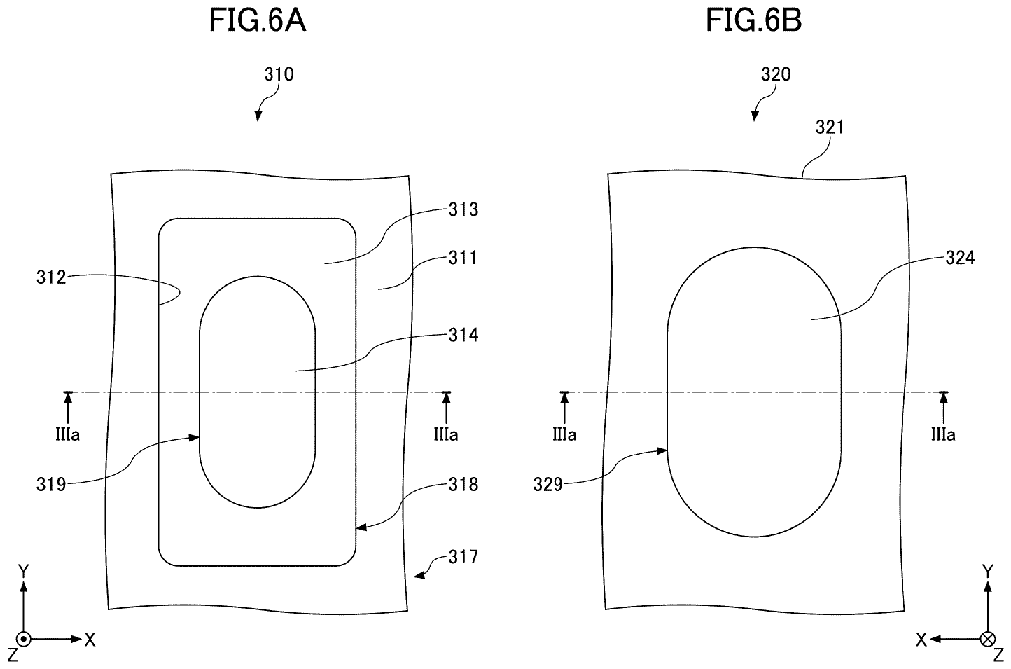

After pressing the metal plate 70 using the molding parts 210 and 220, the metal plate 70 is pressed using molding parts 310 and 320 as illustrated in FIG. 3A. The material of the molding parts 310 and 320 includes a cemented carbide such as tungsten carbide (WC). FIG. 3A corresponds to a cross-section taken along the line IIIa-IIIa in FIGS. 6A and 6B.

As illustrated in FIGS. 3A and 6A, the molding part 310 includes a base portion 317 and a projection 318. A concave portion 319 is formed at the top of the projection 318. The base portion 317 has a flat surface 311 pressed against the first surface 71. The projection 318 is for forming the cavity 50 in the metal plate 70, and the shape of the projection 318 coincides with the shape of the cavity 50. The height of the projection 318 coincides with the depth of the cavity 50. The projection 318 is surrounded by the flat surface 311 and projects from the flat surface 311 to the positive Z side. The projection 318 has sidewall surfaces 312 and a flat surface 313. The sidewall surfaces 312 are connected to the flat surface 311 and are parallel to the Z axis. The shape of the sidewall surfaces 312 coincides with the shape of the sidewall surfaces of the cavity 50. The flat surface 313 is connected to the sidewall surfaces 312 and perpendicular to the Z axis. The shape of the flat surface 313 coincides with the shape of the first flat surface 31, which is the end surface of the cavity 50. The concave portion 319 has a concave surface 314. The concave surface 314 is connected to the flat surface 313 and is recessed toward the negative Z side relative to the flat surface 313. The shape of the concave surface 314 coincides with the shape of the first curved surface 11.

As illustrated in FIGS. 3A and 6B, the molding part 320 has a flat surface 321 pressed against the second surface 72. A concave portion 329 is formed in the molding part 320. The concave portion 329 has a concave surface 324. The concave surface 324 is connected to the flat surface 321 and is recessed toward the positive Z side relative to the flat surface 321. The shape of the concave surface 324 coincides with the shape of the second curved surface 21.

By pressing the metal plate 70 with the molding parts 310 and 320, the thickest part of the metal plate 70 is compressed, which results in the thickness of the thickest part of the metal plate 70 being equal to the thickness of the thickest part of the heat spreader 1, and, also, the cavity 50 is formed in the first surface 71 of the metal plate 70.

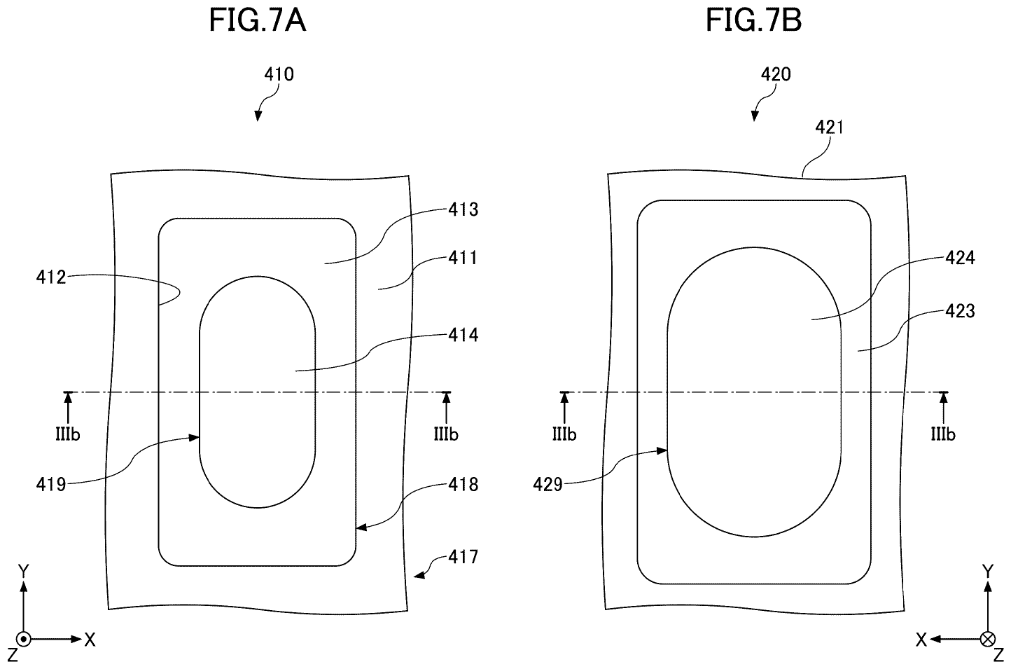

After pressing the metal plate 70 with the molding parts 310 and 320, the metal plate 70 is pressed using molding parts 410 and 420, as illustrated in FIG. 3B. The material of the molding parts 410 and 420 includes cemented carbide such as tungsten carbide (WC). FIG. 3B corresponds to a cross-section taken along the line IIIb-IIIb in FIGS. 7A and 7B.

As illustrated in FIGS. 3B and 7A, the molding part 410 includes a base portion 417 and a projection 418. A concave portion 419 is formed at the top of the projection 418. The base portion 417 has a flat surface 411 pressed against the first surface 71. The shape of the projection 418 coincides with the shape of the cavity 50. The projection 418 is surrounded by the flat surface 411 and projects from the flat surface 411 to the positive Z side. The projection 418 has sidewall surfaces 412 and a flat surface 413. The sidewall surfaces 412 are connected to the flat surface 411 and are parallel to the Z axis. The shape of the sidewall surfaces 412 coincides with the shape of the sidewall surfaces of the cavity 50. The flat surface 413 connects to the sidewall surfaces 412 and is perpendicular to the Z axis. The shape of the flat surface 413 coincides with the shape of the first flat surface 31, which is the end surface of the cavity 50. The concave portion 419 has a concave surface 414. The concave surface 414 is connected to the flat surface 413 and is recessed toward the negative Z side relative to the flat surface 413. The shape of the concave surface 414 coincides with the shape of the first curved surface 11.

As illustrated in FIGS. 3B and 7B, the molding part 420 has a flat surface 421 pressed against the second surface 72. A recess 428 and a concave portion 429 are formed in the molding part 420. The recess 428 has sidewall surfaces 422 and a flat surface 423, which is part of the end surface of the recess. The sidewall surfaces 422 are connected to the flat surface 421 and is parallel to the Z axis. The shape of the sidewall surfaces 422 coincides with the shape of the sidewall surfaces of the flat portion 30. The flat surface 423 is connected to the sidewall surfaces 422 and is perpendicular to the Z axis. The shape of the flat surface 423 coincides with the shape of the second flat surface 32. The concave portion 429 has a concave surface 424. The concave surface 424 is connected to the flat surface 423 and is recessed toward the positive Z side relative to the flat surface 423. The shape of the concave surface 424 coincides with the shape of the second curved surface 21.

By pressing the metal plate 70 with the molding parts 410 and 420, a part of the thickest part of the metal plate 70 is compressed, which shapes the metal plate 70 into the flat portion 30 having the second flat surface 32, the extended portion 40, and the flange portion 60.

After pressing the metal plate 70 with the molding parts 410 and 420, a part of the flange portion 60 is cut as illustrated in FIG. 3C.

By following these steps, the heat spreader 1 according to the first embodiment is effectively manufactured.

### [Method of Making Semiconductor Device Using Heat Spreader]

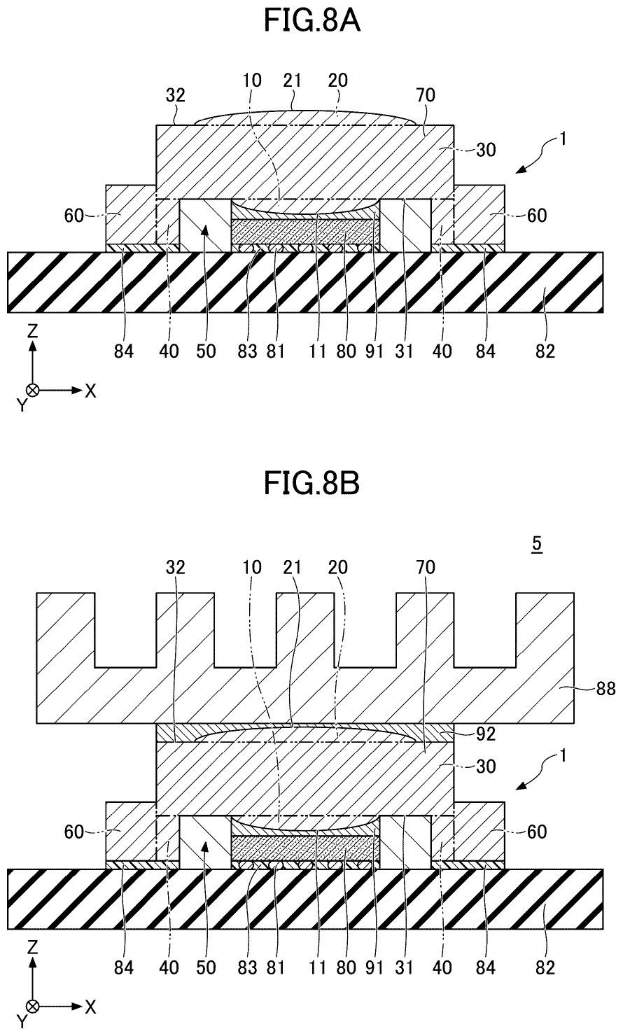

A method of making a semiconductor device using the heat spreader 1 according to the first embodiment will be described below. FIGS. 8A and 8B are cross-sectional views illustrating an example of a method of making a semiconductor device using the heat spreader 1 according to the first embodiment.

As illustrated in FIG. 8A, a mounting substrate 82 on which a semiconductor chip 80 is mounted is prepared. The semiconductor chip 80 has, for example, external terminals 81, and the semiconductor chip 80 is flip-chip mounted on the mounting substrate 82. An underfill resin layer 83 is disposed between the semiconductor chip 80 and the mounting substrate 82.

The heat spreader 1 is then placed on the semiconductor chip 80. In doing so, a paste of a first thermal interface material (TIM) 91 is disposed between the first convex portion 10 and the semiconductor chip 80, and an adhesive 84 is disposed between the mounting substrate 82 and each of the extended portion 40 and the flange portion 60. The first TIM 91 contains, for example, indium (In), and the adhesive 84 contains, for example, silicone resin. Thereafter, the first TIM 91 and the adhesive 84 are hardened while pressing the heat spreader 1 toward the mounting substrate 82 to compress and spread the first TIM 91 and the adhesive 84.

Subsequently, as illustrated in FIG. 8B, a heat sink 88 is placed on the heat spreader 1. In doing so, a paste of a second TIM 92 is disposed between the heat sink 88 and the second convex portion 20. The second TIM 92 contains indium (In), for example. Thereafter, the heat sink 88 is pressed toward the heat spreader 1 to harden the second TIM 92 while compressing and spreading the second TIM 92.

Through the process described above, the manufacture of the semiconductor device 5 is effectively achieved.

Even when the paste of the first TIM 91 contains air, the first convex portion 10 of the heat spreader 1 serves to readily remove the air from the first TIM 91 when compressing and spreading the first TIM 91. Especially, the first curved surface 11 of the first convex portion 10 readily removes the air. With this arrangement, air is unlikely to remain in the first TIM 91 after solidification, which improves the efficiency of heat transfer from the semiconductor chip 80 to the heat spreader 1.

Moreover, even when the paste of the second TIM 92 contains air, the second convex portion 20 of the heat spreader 1 readily removes the air from the second TIM 92 when compressing and spreading the second TIM 92. Especially, the second curved surface 21 of the second convex portion 20 serves to easily remove the air. With this arrangement, air is unlikely to remain in the second TIM 92 after solidification, which improves the efficiency of heat transfer from the heat spreader 1 to the heat sink 88.

As a result, the heat spreader 1 effectively improves the efficiency of heat transfer from the semiconductor chip 80 to the heat sink 88.

In the press working of the metal plate 70 using the molding parts 110 and 120, the first surface 71 and the second surface 72 are simultaneously worked on, thereby forming the first convex portion 10 and the second convex portion 20 simultaneously.

The area of the second convex portion 20 is preferably larger than the area of the first convex portion 10 in plan view. With the area of the second convex portion 20 being larger than the area of the first convex portion 10 in plan view, heat is effectively diffused widely from the first convex portion 10 to the second convex portion 20 when heat generated in the semiconductor chip 80 is transmitted to the heat sink 88 via the heat spreader 1. This arrangement achieves excellent heat transfer characteristics.

In plan view, the first convex portion 10 and the second convex portion 20 may overlap, and the first convex portion 10 may be located inside the second convex portion 20. This arrangement enables heat from the semiconductor chip 80 located toward the first convex portion 10 to be efficiently transmitted to the heat sink 88 located toward the second convex portion 20, thereby improving heat transfer characteristics.

### Second Embodiment

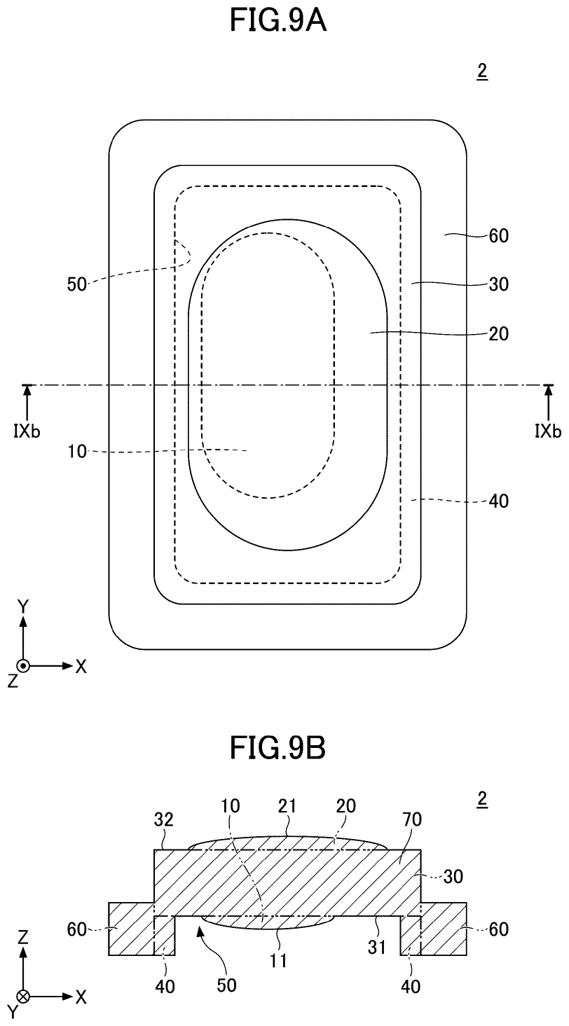

A second embodiment is described below. The second embodiment differs from the first embodiment mainly in the arrangement of the first convex portions 10. FIGS. 9A and 9B are views illustrating an example of a heat spreader according to the second embodiment. FIG. 9A is a plan view and FIG. 9B is a cross-sectional view. FIG. 9B corresponds to a cross-section taken along the line IXb-IXb in FIG. 9A.

As illustrated in FIGS. 9A and 9B, a heat spreader 2 according to the second embodiment is provided such that the center of the first convex portion 10 is located off the center of the cavity 50 in plan view.

Other configurations of the heat spreader 2 are the same as those of the heat spreader 1.

The second embodiment effectively provides the same advantageous effects as the first embodiment. In addition, even when the position of the semiconductor chip 80 on the mounting substrate 82 is asymmetrical relative to the position of the adhesive 84, this arrangement effectively reduces the distance between the first convex portion 10 and the semiconductor chip 80, thereby transmitting the heat generated in the semiconductor chip 80 to the heat spreader 2 with high efficiency.

### Third Embodiment

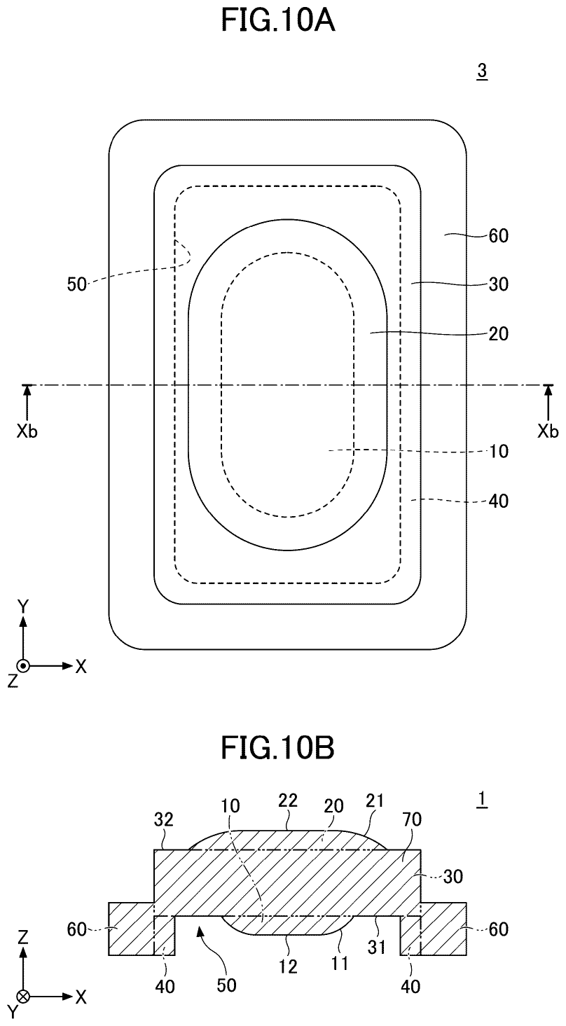

A third embodiment is described below. The third embodiment differs from the first embodiment mainly in the configuration of the first convex portion 10 and the second convex portion 20. FIGS. 10A and 10B are views illustrating an example of a heat spreader according to the third embodiment. FIG. 10A is a plan view and FIG. 10B is a cross-sectional view. FIG. 10B corresponds to a cross-section taken along the line Xb-Xb in FIG. 10A.

As illustrated in FIGS. 10A and 10B, in the heat spreader 3 according to the third embodiment, the surface of the first convex portion 10 toward the negative Z side has a first curved surface 11 and a flat surface 12, and the surface of the second convex portion 20 toward the positive Z side has a second curved surface 21 and a flat surface 22.

The flat surface 12 is located inside the first flat surface 31 in plan view and spaced apart from the first flat surface 31. The first curved surface 11 is located between the first flat surface 31 and the flat surface 12, and is connected to the first flat surface 31 and the flat surface 12, extending toward the negative Z side from the first flat surface 31.

The flat surface 22 is located inside the second flat surface 32 in plan view and spaced apart from the second flat surface 32. The second curved surface 21 is located between the second flat surface 32 and the flat surface 22, and is connected to the second flat surface 32 and the flat surface 22, extending toward the positive Z side from the second flat surface 32.

Other configurations of the heat spreader 3 are the same as those of the heat spreader 1.

The third embodiment effectively provides the same advantageous effects as the first embodiment. The provision of the flat surface 12 of the first convex portion 10 toward the negative Z side effectively reduces the likelihood of tilting of the heat spreader 3 with respect to the semiconductor chip 80. Similarly, the provision of the flat surface 22 of the second convex portion 20 toward the positive Z side effectively reduces the likelihood of tilting of the heat sink 88 with respect to the heat spreader 3.

The planar shape, position, and size of the first convex portion 10 and the second convex portion 20 are independent of each other, and may be selected as appropriate according to the position, size, and the like of the semiconductor chip 80 and the heat sink 88. Further, two or more first convex portions 10 may be provided inside the cavity 50.

According to at least one embodiment, the heat transfer efficiency is effectively improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exhaustively include the subject matter set out in the following clauses.
Clause 1. A method of making a heat spreader, comprising:
   preparing a metal plate having a first surface and a second surface opposite the first surface; and
   performing one or more pressing processes on the metal plate, thereby shaping the metal plate into:
   a flat portion having a first flat surface and a second flat surface opposite the first flat surface;
   a first convex portion surrounded by the first flat surface and projecting from the first flat surface to a side opposite the second flat surface; and
   a second convex portion surrounded by the second flat surface and projecting from the second flat surface to a side opposite the first flat surface,
   wherein the first flat surface is formed on the first surface, and the second flat surface is formed on the second surface.
Clause 2. The method according to clause 1, wherein the shaping the metal plate into the flat portion, the first convex portion, and the second convex portion involves simultaneously shaping the first surface and the second surface.
Clause 3. The method according to clause 1, wherein the performing the one or more pressing processes includes forming an extended portion that connects to the flat portion and that extends from the first flat surface to the side opposite the second flat surface.
Clause 4. The method according to clause 3, wherein in plan view, the extended portion surrounds the first convex portion.
Clause 5. The method according to clause 1, wherein the first convex portion has a first curved surface connecting to the first flat surface and extending from the first flat surface to the side opposite the second flat surface, and
   the second convex portion has a second curved surface connecting to the second flat surface and extending from the second flat surface to the side opposite the first flat surface.
Clause 6. The method according to clause 1, wherein the second convex portion is larger in area than the first convex portion in plan view.

What is claimed is:

1. A heat spreader comprising:
a flat portion having a first flat surface and a second flat surface opposite the first flat surface;
a first convex portion surrounded by the first flat surface and projecting from the first flat surface to a side opposite the second flat surface; and
a second convex portion surrounded by the second flat surface and projecting from the second flat surface to a side opposite the first flat surface.

2. The heat spreader according to claim 1, further comprising an extended portion connected to the flat portion and extending from the first flat surface to the side opposite the second flat surface.

3. The heat spreader according to claim 2, wherein in plan view, the extended portion surrounds the first convex portion.

4. The heat spreader according to claim 2, wherein the flat portion and the extended portion are formed of one metal plate.

5. The heat spreader according to claim 1, wherein the first convex portion has a first curved surface connected to the first flat surface and extending from the first flat surface to the side opposite the second flat surface, and
the second convex portion has a second curved surface connected to the second flat surface and extending from the second flat surface to the side opposite the first flat surface.

6. The heat spreader according to claim 1, wherein the second convex portion is larger in area than the first convex portion in plan view.

7. The heat spreader according to claim 1, wherein a height of the first convex portion from the first flat surface is from 0.005 mm to 0.5 mm, and a height of the second convex portion from the second flat surface is from 0.005 mm to 0.5 mm.

8. The heat spreader according to claim 2, wherein a cavity is defined by the first flat surface, the first convex portion, and the extended portion.

9. The heat spreader according to claim 8, wherein a depth of the cavity is from 0.1 mm to 1 mm.

10. The heat spreader according to claim 1, wherein the first convex portion overlaps with the second convex portion in plan view.

11. The heat spreader according to claim 10, wherein the first convex portion is located inside the second convex portion in plan view.
